(19) United States
(12) Patent Application Publication
(10) Pub. No.: US 2026/0305069 A1
(43) Pub. Date: Oct. 1, 2026

(54) METHOD FOR MANUFACTURING DISPLAY DEVICE INCLUDING RECESSED PATTERN AND ELECTRONIC DEVICE INCLUDING THE DISPLAY DEVICE

(71) Applicant: SAMSUNG DISPLAY CO., LTD., YONGIN-SI (KR)

(72) Inventors: HYEONSIK KIM, Yongin-si (KR); GUN HEE KIM, Yongin-si (KR); JUNGWOO PARK, Yongin-si (KR); KWANG SOO BAE, Yongin-si (KR); TAEKYUNG AHN, Yongin-si (KR)

(21) Appl. No.: 19/454,731

(22) Filed: Jan. 21, 2026

(30) Foreign Application Priority Data
Mar. 27, 2025 (KR) 10-2025-0039690

(51) Int. Cl. H10K 59/12; H10K 59/122; H10K 59/35

(52) U.S. Cl. CPC H10K 59/1201; H10K 59/122; H10K 59/352

(57) ABSTRACT

A method for manufacturing a display device including providing a preliminary display device including a base layer, and a display element layer disposed on the base layer. The display element layer includes a pixel-defining layer having pixel openings, and first electrodes disposed in the pixel openings. A portion of the first electrodes is covered by the pixel-defining layer. The method includes forming blocking particles on the first electrode and the pixel-defining layer, forming a recessed pattern by performing dry etching on the preliminary display device using the blocking particles, and removing the blocking particles by performing wet etching.

### CROSS-REFERENCE TO RELATED APPLICATIONS

This U.S. non-provisional patent application claims priority under 35 U.S.C. § 119 to Korean Patent Application No. 10-2025-0039690, filed on Mar. 27, 2025, the entire contents of which are hereby incorporated by reference.

### TECHNICAL FIELD

The present disclosure relates to a method for manufacturing a display device and, more particularly to, a method for manufacturing a display device including a recessed pattern and electronic device including the display device.

### DISCUSSION OF RELATED ART

A display device displays images and provides various functions that enable a user to interact with the display device, such as providing information to the user or detecting a user's input. In some cases, display devices are able to detect user-provided information (for example, biometric information or other externally applied information). Methods for recognizing user information may include capacitive method, optical method, or ultrasonic method. For example, the capacitive method may detect a variation in capacitance between electrodes. The optical method may detect incident light using a photo sensor. The ultrasonic method may detect vibration using a piezoelectric material or other similar materials. However, these recognition methods may encounter challenges such as lateral leakage current.

### SUMMARY

The present disclosure provides a method for manufacturing a display device capable of detecting light using a photo sensor. The present disclosure also provides a method for manufacturing a display device in which a lateral leakage current is reduced.

An embodiment of the inventive concept provides a method for manufacturing a display device, the method includes providing a preliminary display device including a base layer, and a display element layer disposed on the base layer. The display element layer includes a pixel-defining layer having pixel openings, and first electrodes disposed in the pixel openings. A portion of the first electrodes is covered by the pixel-defining layer. The method includes forming blocking particles on the first electrode and the pixel-defining layer, forming a recessed pattern by performing dry etching on the preliminary display device using the blocking particles, and removing the blocking particles by performing wet etching.

In an embodiment, the blocking particles may be randomly arranged on the first electrode and the pixel-defining layer.

In an embodiment, the method may further include forming a photoresist in the pixel openings. The photoresist may cover at least some of the blocking particles.

In an embodiment, the method may further include removing the photoresist using a stripping process.

In an embodiment, the preliminary display device may further include protective layers disposed on the first electrodes. At least some portions of the protective layers may be covered by the pixel-defining layer.

In an embodiment, the protective layers may include an inorganic oxide.

In an embodiment, the method may further include performing wet etching on the protective layers in the pixel opening.

In an embodiment, a portion of the protective layer may be disposed between the pixel-defining layer and the first electrode.

In an embodiment, the blocking particles may each include metal.

In an embodiment, the metal may include at least one of silver (Ag), aluminum (Al), titanium (Ti), molybdenum (Mo), or nickel (Ni).

In an embodiment, each of the blocking particles may have an island shape.

In an embodiment, the blocking particles may have a maximum width of about 0.1 μm to about 10 μm.

In an embodiment, at least some of the blocking particles may be spaced apart from each other.

In an embodiment, the blocking particles may be formed by performing at least one of a sputtering process, a chemical vapor deposition process, or a nano imprint process.

In an embodiment, the recessed pattern may be formed by etching an upper surface of the pixel-defining layer toward the base layer.

In an embodiment, the recessed patterns might not overlap the blocking particles.

In an embodiment, a depth of the recessed pattern may be greater than a width of each of the blocking particles, and the recessed patterns might not penetrate the pixel-defining layer.

In an embodiment, the base layer may include first, second, and third light-emitting regions and a photo-sensing region, the photo-sensing region may be surrounded by the first, second, and third light-emitting regions, the first light-emitting region may emit red light, the second light-emitting region may emit green light, and the third light-emitting region may emit blue light.

In an embodiment of the inventive concept, a method for manufacturing an electronic device including a display device, a processor, and a battery, the method includes providing a preliminary display device including a base layer, and a display element layer disposed on the base layer. The display element layer includes a pixel-defining layer having pixel openings, and first electrodes disposed in the pixel openings. A portion of the first electrodes is covered by the pixel-defining layer. The method includes forming blocking particles on the first electrode and the pixel-defining layer, forming a recessed pattern by performing dry etching on the preliminary display device using the blocking particles, and removing the blocking particles by performing wet etching.

In an embodiment of the inventive concept, an electronic device configured to provide an image, includes a display device, a processor, and a battery. The display device is manufactured using a method including providing a preliminary display device including a base layer, and a display element layer disposed on the base layer. The display element layer includes a pixel-defining layer having pixel openings, and first electrodes disposed in the pixel openings. A portion of the first electrodes is covered by the pixel-defining layer. The method includes forming blocking particles on the first electrode and the pixel-defining layer, forming a recessed pattern by performing dry etching on the preliminary display device using the blocking particles, and removing the blocking particles by performing wet etching.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a perspective view of an electronic device according to an embodiment of the inventive concept;

FIG. 2 is an exploded perspective view of an electronic device according to an embodiment of the inventive concept;

FIG. 3 is a cross-sectional view of a display device according to an embodiment of the inventive concept;

FIG. 4 is a block diagram of a display device according to an embodiment of the inventive concept;

FIG. 5A is an enlarged view of a part of a display region according to an embodiment of the inventive concept;

FIG. 5B is an enlarged view of a region AA′ of FIG. 5A;

FIG. 6 is a cross-sectional view taken along line I-I′ of FIG. 5A;

FIGS. 7A and 7B are enlarged views of a part of FIG. 6;

FIG. 8 is a flowchart illustrating a method for manufacturing a display device according to an embodiment of the inventive concept;

FIGS. 9A, 9B, 9C, 9D, 9E, and 9F are views illustrating each step in a method for manufacturing a display device according to an embodiment of the inventive concept;

FIG. 10 is a flowchart illustrating a method for manufacturing a display device according to an embodiment of the inventive concept;

FIGS. 11A, 11B, 11C, and 11D are views illustrating each step in a method for manufacturing a display device according to an embodiment of the inventive concept;

FIG. 12 is a block diagram of an electronic device according to an embodiment of the inventive concept; and

FIG. 13 is a schematic view illustrating electronic devices according to various embodiments.

### DETAILED DESCRIPTION

The inventive concept may be implemented and modified in various forms, and specific embodiments are illustrated in the drawings and described in the detailed description. It is to be understood, however, that the inventive concept is not necessarily intended to be limited to the particular forms disclosed, and is intended to cover all modifications, equivalents, and alternatives without departing from the spirit and scope of the inventive concept.

In the present disclosure, when an element (or a region, a layer, a portion, or the like) is referred to as being “on”, “connected to” or “coupled to” another element, the element may be directly disposed on, connected to, or coupled to the other element, or one or more elements may be disposed therebetween. For example, intervening regions, layers or portions may be present between the regions, layers, or portions, respectively.

Like reference numerals or symbols refer to like elements throughout the disclosure and the drawings. For example, while each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like. As used herein, the term “and/or” includes any and all combinations of one or more of the associated listed elements.

It will be understood that, although the terms “first”, “second”, etc. may be used herein to describe various elements, the elements are not necessarily limited by these terms. These terms are used to distinguish one element from another element. For example, a first element could be termed a second element, or vice versa, without departing from the scope of the inventive concept. In the present disclosure, the singular expressions “a”, “an” and “the” are intended to include the plural forms as well, unless the context clearly indicates otherwise.

In addition, the terms “below”, “under”, “on the lower side”, “above”, “over”, “on the upper side”, or the like may be used to describe the relationships between the elements illustrated in the drawings. These terms are relative concepts and are described on the basis of the directions indicated in the drawings.

It will be further understood that the terms “comprises, includes, has” and/or “comprising, including, having”, when used in the present disclosure, specify the presence of stated features, numbers, steps, operations, elements, components or combinations thereof, but do not preclude the possibility of the presence or addition of one or more other features, numbers, steps, operations, elements, components, and/or combinations thereof.

Hereinafter, embodiments of the inventive concept are described with reference to the drawings.

Embodiments of the present disclosure provide a display device including a pixel-defining layer patterned using blocking particles deposited in an island shape. The blocking particles are randomly formed on the pixel-defining layer and first electrodes. During a dry etching process, the blocking particles function as localized hard masks to form recessed patterns in an upper surface of the pixel-defining layer. The recessed patterns are distributed in non-light-emitting regions adjacent to light-emitting elements and photo-sensing elements. By increasing the effective leakage path length or introducing disconnections in stacked layers, the recessed patterns reduce lateral leakage currents between the light-emitting elements and the photo-sensing elements, thereby improving sensing accuracy.

In some embodiments, protective layers are disposed on the first electrodes prior to the deposition of the blocking particles. Portions of the protective layers may remain after wet etching, thereby forming as the remaining protective layers disposed between the pixel-defining layer and the first electrodes. Accordingly, the remaining protective layers and the recessed patterns in the pixel-defining layer may suppress lateral leakage current.

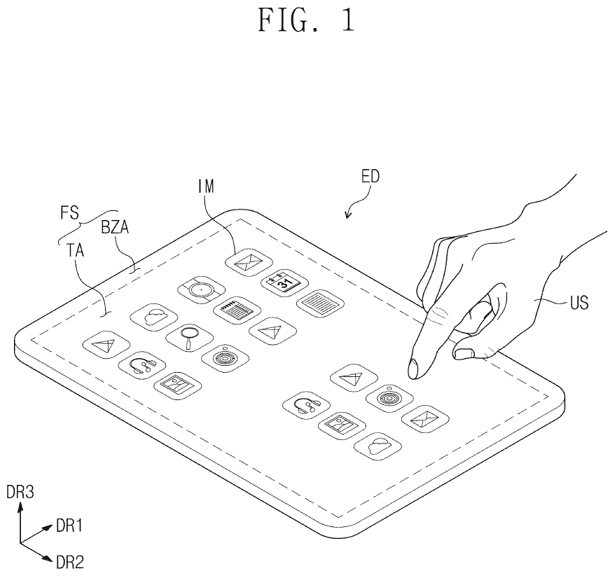

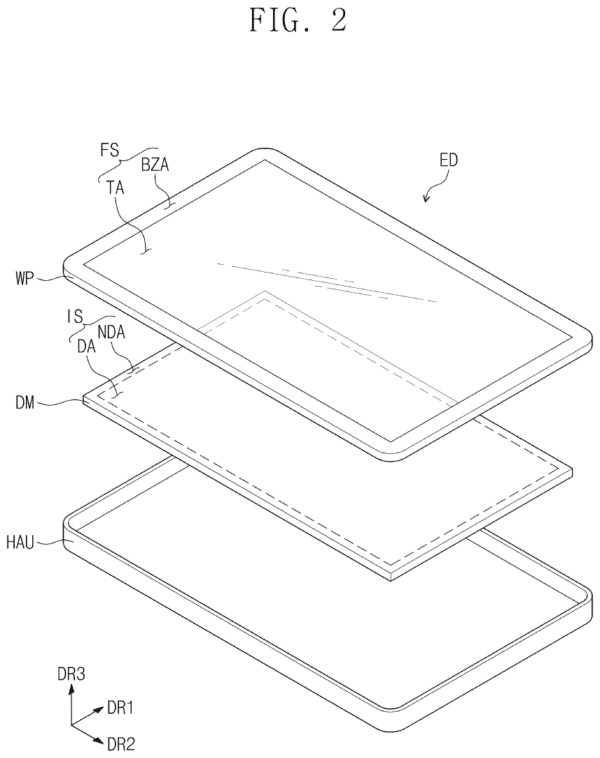

FIG. 1 is a perspective view of an electronic device according to an embodiment of the inventive concept. FIG. 2 is an exploded perspective view of an electronic device according to an embodiment of the inventive concept.

In an embodiment, an electronic device ED may have a rectangular shape with short sides extending in a first direction DR1 and long sides extending in a second direction DR2 crossing (or perpendicular to) the first direction DR1. In one aspect, the first direction DR1 and a second direction may form a plane. However, an embodiment of the inventive concept is not necessarily limited thereto, and the electronic device ED may have various shapes such as a circular shape, a polygonal shape, or other geometric shapes.

The electronic device ED may display an image IM in a third direction DR3 through a display surface FS parallel to a plane defined by the first direction DR1 and the second direction DR2. The third direction DR3 may be substantially parallel to a normal direction of the display surface FS. The display surface FS may correspond to a front surface of the electronic device ED. The image IM may include a dynamic image (e.g., a video) and/or a static image. In FIG. 1, application icons are illustratively shown as the image IM.

In an embodiment, a front surface (or an upper surface) and a rear surface (or a lower surface) of each member or unit may be represented based on the direction in which the image IM is displayed. The front and rear surfaces may be opposed to each other in the third direction DR3, and the normal direction of each of the front and rear surfaces may be parallel to the third direction DR3. A spacing distance between the front surface and the rear surface along the third direction DR3 may correspond to a thickness of a member, unit, or stacked structure.

In the present disclosure, the term “on a plane” may be defined as a state when viewed in the third direction DR3. In the present disclosure, the term “on a cross section” may represent a state when viewed in the first direction DR1 or the second direction DR2. Meanwhile, directions indicated by the first, second, and third directions DR1, DR2, and DR3 are relative and may be redefined with respect to alternative orientations.

In the electronic device ED, the display surface FS may correspond to the front surface of the electronic device ED, and may correspond to the front surface FS of a window WP (see FIG. 2). Hereinafter, the same reference numerals or symbols are used for the display surface, the front surface of the electronic device ED, and the front surface of the window WP. In some cases, the electronic device ED may include a foldable display device including a folding region and a non-folding region, or a bendable display device including at least one bending portion.

In an embodiment, the electronic device ED may detect an external input applied from the outside. The external input may include various types of inputs applied from the outside of the electronic device ED. For example, the external input may include force, pressure, temperature, light, or other physical or optical inputs. The external input may include an input through direct contact, such as a touch by a hand or stylus as well as an input applied without contact, such as a hovering action within a predetermined distance of the display device DD. FIG. 1 illustrates an embodiment in which the electronic device ED detects fingerprint information provided by an external object.

Referring to FIG. 2, an electronic device ED may include a window WP, a display module DM, and a housing HAU.

The window WP may include an optically transparent insulating material. The window WP may include a transmission region TA and a bezel region BZA. An image is viewable through the transmission region TA corresponding to a front surface FS of the window WP.

The transmission region TA may be an optically transparent region. The bezel region BZA may be a region having a lower light transmittance than the transmission region TA. The bezel region BZA may have a predetermined color. The bezel region BZA may be adjacent to the transmission region TA and surround the transmission region TA. The bezel region BZA may define a shape of the transmission region TA. However, an embodiment is not necessarily limited to the example illustrated in FIG. 2. For example, the bezel region BZA may be disposed adjacent to one side of the transmission region TA, or a portion of the bezel region BZA might not be included.

FIGS. 1 and 2 illustrate the transmission region TA as having a quadrangular shape. However, this is merely illustrated as an example. The transmission region TA may have various shapes, and is not necessarily limited to the embodiment illustrated in FIGS. 1 and 2.

The display module DM may be disposed below the window WP. The display module DM may be a component configured to generate an image IM. The image IM generated from the display module DM is displayed on a display surface IS, and is viewed externally through the transmission region TA.

The display module DM includes a display region DA and a non-display region NDA. The display region DA may be activated in response to an electrical signal. The non-display region NDA may be covered by the bezel region BZA. The non-display region NDA is adjacent to the display region DA. The non-display region NDA may surround the display region DA. In some cases, the non-display region NDA may completely or partially surround the display region DA.

The housing HAU may accommodate a display device DD. The housing HAU may provide a base space for the display device DD. The housing HAU may be disposed to cover the display module DM, such that an upper surface of the display surface IS of the electronic device ED is exposed. The housing HAU may cover side surfaces and a bottom surface of the display module DM, and expose the top surface of the display module DM. However, an embodiment is not necessarily limited thereto, and the housing HAU may cover a portion of the top surface as well as the side surfaces and the bottom surface of the display module DM.

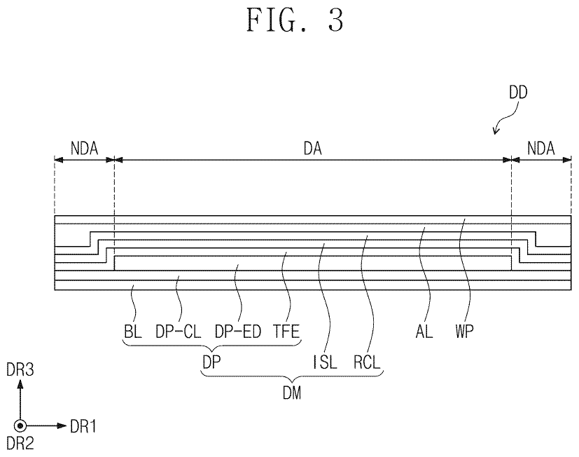

FIG. 3 is a cross-sectional view of a display device according to an embodiment of the inventive concept.

Referring to FIG. 3, a display module DM may include a display panel DP, an input-sensing layer ISL, and an optical layer RCL. The display panel DP may include a base layer BL, a circuit element layer DP-CL, a display element layer DP-ED, and an encapsulation layer TFE. In some embodiments, a window WP may be disposed on the optical layer RCL. For example, an adhesive layer AL may be disposed between the window WP and the optical layer RCL.

The display panel DP may be a component configured to generate an image. The display panel DP may be a light-emitting type display panel, but is not necessarily limited thereto. For example, the display panel DP may include an organic light-emitting display panel, an inorganic light-emitting display panel, or a quantum dot light-emitting display panel. A light-emitting layer of the organic light-emitting display panel may include an organic light-emitting material, and a light-emitting layer of the inorganic light-emitting display panel may include an inorganic light-emitting material. A light-emitting layer of the quantum dot light-emitting display panel may include quantum dots, quantum rods, or other nanoscale light-emitting structures. Hereinafter, the display panel DP is described as an organic light-emitting display panel.

The display panel DP may include the base layer BL, the circuit element layer DP-CL, the display element layer DP-ED, and the encapsulation layer TFE. The display panel DP may be a flexible display panel. However, the inventive concept is not necessarily limited thereto. For example, the display panel DP may be a rigid display panel, or a foldable display panel configured to fold about a folding axis.

The base layer BL may provide a base surface on which the circuit element layer DP-CL is disposed. The base layer BL may include a glass substrate, a metal substrate, a polymer substrate, or an organic/inorganic composite substrate.

The circuit element layer DP-CL may be disposed on the base layer BL. The circuit element layer DP-CL may include at least one insulating layer, a circuit element, signal lines, or signal pads. The circuit element layer DP-CL may include a pixel driving circuit configured to drive each of a plurality of pixels that display an image, a sensor driving circuit configured to drive sensors that recognize external information, and other functional circuits. For example, the external information may be biometric information. For example, the sensor may be a fingerprint recognition sensor, a proximity sensor, an iris recognition sensor, or other biometric detection sensor. Additionally, the sensor may be a photo sensor configured to optically recognize biometric information. The circuit element layer DP-CL may further include signal lines electrically connected to the pixel driving circuit and/or the sensor driving circuit.

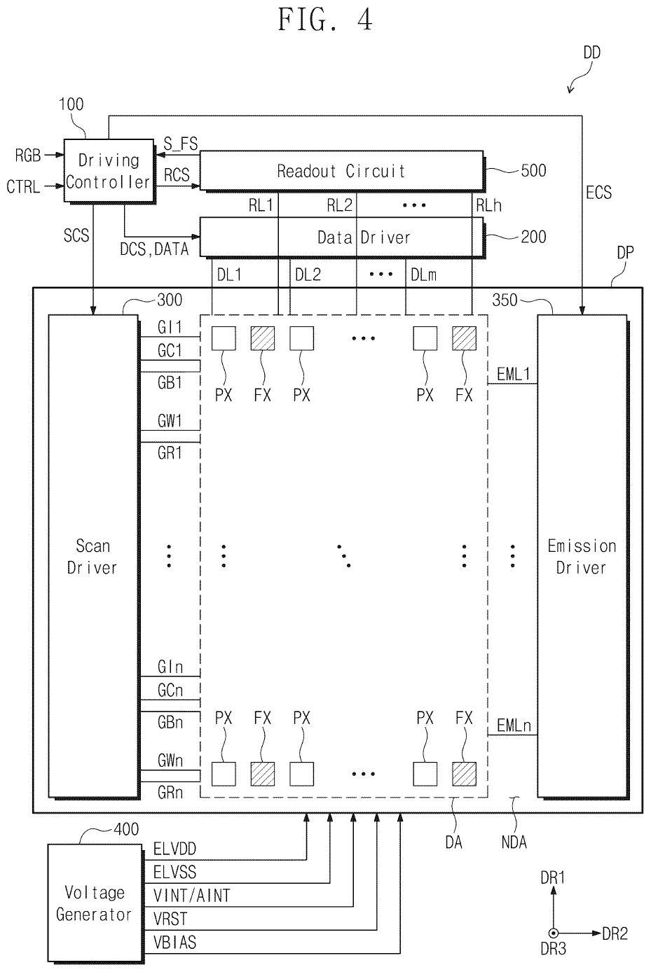

The display element layer DP-ED may be disposed on the circuit element layer DP-CL. The display element layer DP-ED may include light-emitting elements overlapping a display region DA. The light-emitting elements of the display element layer DP-ED may be electrically connected with corresponding circuit elements in the circuit element layer DP-CL to form pixels PX (see FIG. 4). The pixels PX may each output light through the display region DA in response to a driving signal.

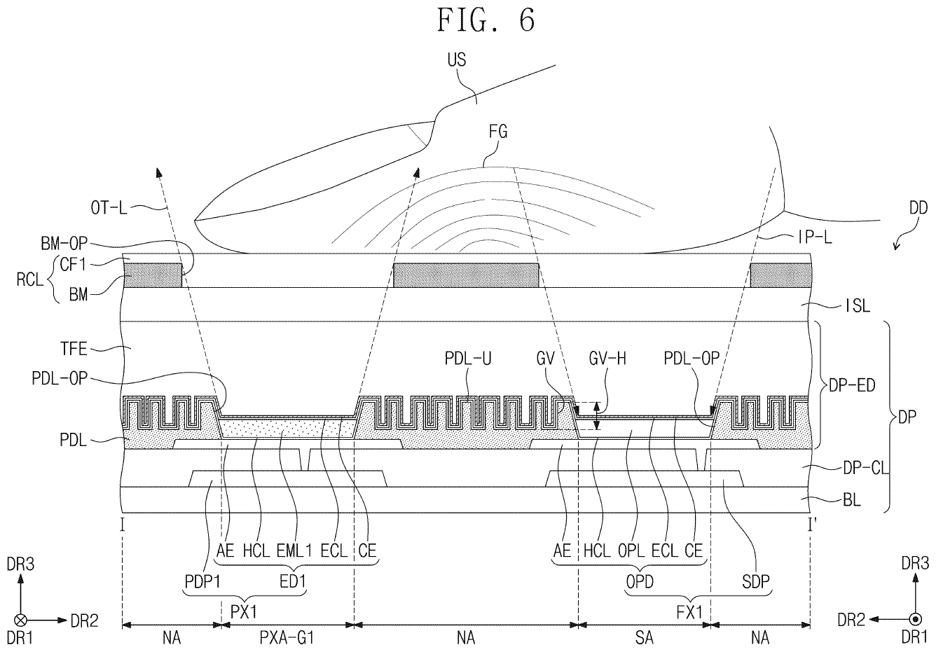

The display element layer DP-ED may include photo-sensing elements OPD (see FIG. 6) overlapping the display region DA. The photo-sensing element OPD may be a photo sensor configured to sense light incident toward the photo-sensing element and convert an optical signal into an electrical signal. For example, the photo-sensing element OPD may be a photo diode. Further structural and operational details of the photo-sensing element OPD are described with reference to FIG. 6.

The encapsulation layer TFE may be disposed on the display element layer DP-ED and seal the display element layer DP-ED. The encapsulation layer TFE may include at least one organic film and at least one inorganic film. The inorganic film may include an inorganic material and protect the display element layer DP-ED against moisture and/or oxygen. The inorganic film may include a silicon nitride layer, a silicon oxynitride layer, a silicon oxide layer, a titanium oxide layer, an aluminum oxide layer, or other similar inorganic protective material. The organic layer may include an organic material and protect the display element layer DP-ED against foreign substances such as dust particles.

The input-sensing layer ISL may be disposed on the display panel DP. The input-sensing layer ISL may be directly disposed on the encapsulation layer TFE. In the present disclosure, the term, “directly disposed” may represent that no separate adhesive layer, adhesive member, or other intervening layer is disposed therebetween, and a component may be formed through a continuous process. For example, the phrase, “the input-sensing layer ISL is directly disposed on the display panel DP” may represent that after the display panel DP is formed, the input-sensing layer ISL is formed on a base surface of the display panel DP through a continuous process without a separate adhesive layer.

In some cases, the input-sensing layer ISL is not necessarily limited thereto, and may be bonded to the display panel DP via an adhesive layer. The input-sensing layer ISL may be manufactured through a separate process from the display panel DP, and then attached to an upper surface of the display panel DP via an adhesive layer.

The input-sensing layer ISL may detect an external input applied from the outside and obtain coordinate information corresponding to the detected input. The input-sensing layer ISL may operate in various manners, such as a capacitive, a resistive, an infrared, a sonic, or a pressure sensing, and is not necessarily limited to a particular mode. For example, the input-sensing layer ISL may be driven through the capacitive manner and include a plurality of sensing electrodes for detecting an external input. The input-sensing layer ISL may provide an input signal to the display panel DP, enabling the display panel DP to generate an image corresponding to the detected external input.

The optical layer RCL may be disposed on the input-sensing layer ISL. The optical layer RCL may be directly disposed on the input-sensing layer ISL. For example, the optical layer RCL may be formed by applying (or printing) a composition for the optical layer RCL on a base surface provided by the input-sensing layer ISL. In an embodiment, the optical layer RCL may be formed through spin coating, inkjet printing, or other deposition methods.

The optical layer RCL may reduce reflectance of external light incident from the outside of the display device DD. The optical layer RCL may include a light blocking layer BM (see FIG. 6) and a plurality of color filters. The color filters may be configured to selectively transmit red, green, and blue light, thereby enabling full-color image reproduction and maintaining optical isolation for photo-sensing regions.

The display device DD may further include an adhesive layer AL disposed between the display module DM and the window WP. The display module DM and the window WP may be bonded via the adhesive layer AL disposed between the display module DM and the window WP. The adhesive layer AL may include a transparent adhesive, such as an optically clear adhesive film (OCA), an optically clear resin (OCR), or a pressure sensitive adhesive film (PSA). However, in the adhesive composition of the adhesive layer AL is not necessarily limited thereto.

FIG. 4 is a block diagram of a display device according to an embodiment of the inventive concept.

Referring to FIG. 4, a display device DD includes a display panel DP, a driving controller 100, and a driving circuit. For example, the driving circuit of the display device DD includes a data driver 200, a scan driver 300, an emission driver 350, a voltage generator 400, and a readout circuit 500. In an embodiment, the voltage generator 400, the readout circuit 500, and the driving controller 100 may be implemented as one driving chip.

The display panel DP may include a plurality of pixels PX disposed in a display region DA, and photo sensors FX disposed within the display region DA. For example, the photo sensors FX may each be disposed between two pixels PX adjacent to each other. However, an arrangement relationship between the photo sensors FX and the pixels PX is not necessarily limited thereto. For example, the photo sensors FX may be disposed between three or more adjacent pixels PX.

The display panel DP may include initialization scan lines GI1 to GIn, compensation scan lines GC1 to GCn, bias scan lines GB1 to GBn, write scan lines GW1 to GWn, emission control lines EML1 to EMLn, reset scan lines GR1 to GRn, data lines DL1 to DLm, and readout lines RL1 to RLh. For example, n is a natural number greater than 1. These lines may be configured to provide driving, data transfer, and signal functions for both image display and optical sensing operations.

A plurality of pixels PX are electrically connected to the initialization scan lines GI1 to GIn, the compensation scan lines GC1 to GCn, the write scan lines GW1 to GWn, the bias scan lines GB1 to GBn, the emission control lines EML1 to EMLn, and the data lines DL1 to DLm. However, the number of signal lines connected to each of the pixels PX, is not necessarily limited thereto, and may vary based on design requirements.

The photo sensors FX are electrically connected to the write scan lines GW1 to GWn, the reset scan lines GR1 to GRn, and the readout lines RL1 to RLh. However, the number of the signal lines connected to each of the photo sensors FX, is not necessarily limited thereto, and may vary based on design requirements.

The driving controller 100 receives an image signal RGB and a control signal CTRL. The driving controller 100 generates an image data signal DATA by converting the image signal RGB into a format compatible with the data driver 200. The driving controller 100 outputs a first control signal DCS, a second control signal SCS, a third control signal ECS, and a fourth control signal RCS.

The data driver 200 receives the first control signal DCS and the image data signal DATA from the driving controller 100. The data driver 200 converts the image data signal DATA into data signals, and outputs the data signals to a plurality of data lines DL1 to DLm. The data signals include analog voltages corresponding to gray level values of the image data signal DATA.

The scan driver 300 receives the second control signal SCS from the driving controller 100. The scan driver 300 generates initialization scan signals to the initialization scan lines GI1 to GIn, and generates compensation scan signals to the compensation scan lines GC1 to GCn in response to the second control signal SCS. Additionally, the scan driver 300 may generate write scan signals to the write scan lines GW1 to GWn, and generate black scan signals to the bias scan lines GB1 to GBn in response to the second control signal SCS. Furthermore, the scan driver 300 may output reset scan signals to the reset scan lines GR1 to GRn in response to the second control signal SCS.

The emission driver 350 receives the third control signal ECS from the driving controller 100. The emission driver 350 may output emission control signals to the emission control lines EML1 to EMLn in response to the third control signal ECS. Alternatively, the scan driver 300 may be connected to the emission control lines EML1 to EMLn. In an embodiment, the display device DD might not include the emission driver 350, and the scan driver 300 may output the emission control signals to the emission control lines EML1 to EMLn.

The readout circuit 500 receives the fourth control signal RCS from the driving controller 100. The readout circuit 500 may receive sensing signals from the readout lines RL1 to RLh in response to the fourth control signal RCS. The readout circuit 500 may process the sensing signals and provide processed sensing signals S_FS to the driving controller 100. The driving controller 100 may recognize biometric information based on the sensing signals S_FS.

The voltage generator 400 generates voltages for operating the display panel DP. In an embodiment, the voltage generator 400 may generate a first driving voltage ELVDD, a second driving voltage ELVSS having a voltage level lower than the first driving voltage ELVDD, a first initialization voltage VINT, a second initialization voltage AINT, a reset voltage VRST, and a bias voltage VBIAS. For example, the voltage generator 400 may provide one or more of these voltages to a corresponding controller or driver to operate the display panel.

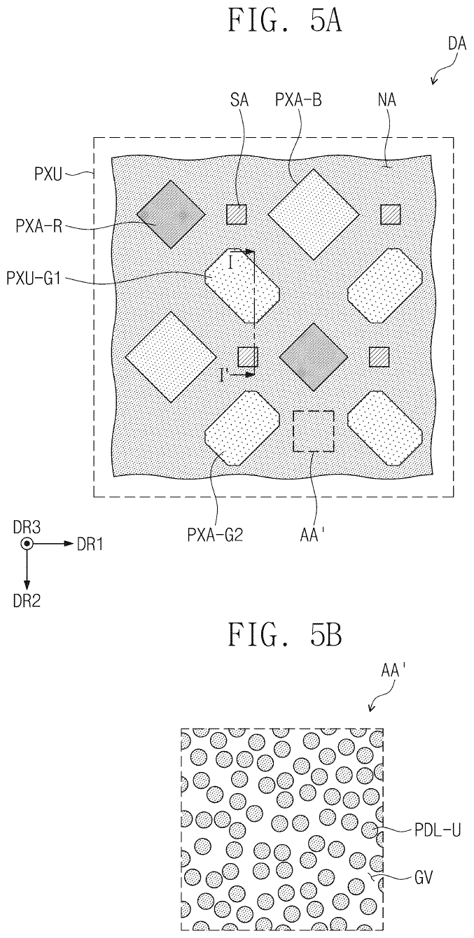

FIG. 5A is an enlarged view of a part of a display region according to an embodiment of the inventive concept. FIG. 5B is an enlarged view of a region AA′ of FIG. 5A.

FIG. 5A is an enlarged view illustrating one pixel unit PXU of a display region of a display device. For example, FIG. 5A illustrates one pixel unit PXU in which light-emitting regions and photo-sensing regions are integrally arranged within a pixel-defining layer patterned by recessed structures.

A display region DA may include light-emitting regions PXA-G1, PXA-G2, PXA-R, and PXA-B, a non-light-emitting region NA, and a photo-sensing region SA. A first light-emitting region PXA-G1, a second light-emitting region PXA-G2, a third light-emitting region PXA-R, and a fourth light-emitting region PXA-B, and the photo-sensing region SA, which are disposed adjacent to each other, may be grouped as one “pixel unit PXU”. In some cases, a plurality of pixel units PXU may be arranged in the first direction DR1 and the second direction DR2. In some embodiments, recessed patterns GV within the pixel-defining layer PDL of the non-light-emitting region NA may surround the pixel unit PXU to extend or disconnect lateral leakage paths between adjacent light-emitting regions and the photo-sensing region.

For example, FIG. 5A illustrates that one pixel unit PXU includes a plurality of light-emitting regions PXA-G1, PXA-G2, PXA-R, and PXA-B, and four photo-sensing regions SA. However, a configuration and an arrangement of the pixel unit PXU are not necessarily limited the example illustrated. In some embodiments, the pixel unit PXU may include additional light-emitting regions emitting white or yellow light or fewer photo-sensing regions.

The non-light-emitting region NA may be a region overlapping a pixel-defining layer PDL (see FIG. 6). In one aspect, FIG. 5A may be illustrated without a planar arrangement of recessed patterns GV within the pixel-defining layer PDL.

The AA′ region may be a partial region of an upper surface PDL-U of the pixel-defining layer PDL. As illustrated in FIG. 5B, the recessed patterns GV are randomly distributed across the upper surface PDL-U of the pixel-defining layer PDL.

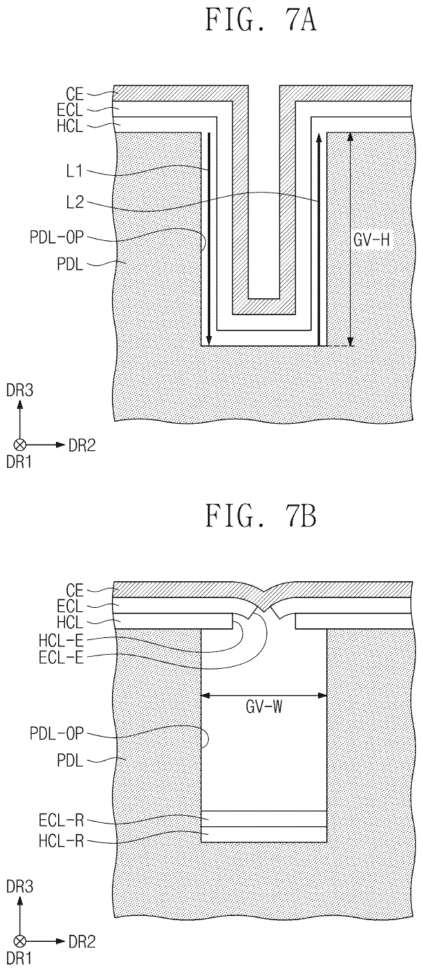

Referring to FIG. 5B, the recessed patterns GV may be defined in the pixel-defining layer PDL. The upper surface PDL-U of the pixel-defining layer PDL may be recessed along a direction opposed to the third direction DR3, thereby forming the recessed patterns GV. In some cases, for example, the recessed patterns GV are formed by a hard masking effect in which island-shaped blocking particles deposited on the pixel-defining layer PDL act as etching masks during dry etching. Accordingly, positions of the recessed patterns GV are randomly distributed based on the arrangement of the blocking particles without a separately patterned separator. The random distribution increases the effective leakage path length between adjacent electrodes and thereby reduces local leakage current. Further detail on the recessed patterns GV is described with reference to FIGS. 6, 7A, and 7B.

FIG. 6 is a cross-sectional view taken along line I-I′ of FIG. 5A. For example, FIG. 6 illustrates recessed patterns GV formed in a pixel-defining layer PDL by a hard masking process using island-shaped blocking particles.

FIG. 6 exemplarily illustrates a state in which a photo sensor FX recognizes a fingerprint FG, which is one among a plurality of pieces of biometric information input via a body part (e.g., finger) of a user US. For convenience of description, FIG. 6 illustrates that the width of a first light-emitting region PXA-G1 is the same as the width of a photo-sensing region SA. However, an embodiment of the inventive concept is not necessarily limited to the illustrated example. For example, the width of the first light-emitting region PXA-G1 may be greater than the width of the photo-sensing region SA. For example, widths of light-emitting regions and photo-sensing regions may be adjusted independently based on optical efficiency, sensor resolution, or leakage current suppression requirements.

FIG. 6 exemplarily illustrates a first pixel PX1 as a pixel, but the description thereof may be applied to a second pixel and a third pixel in the same/similar manner.

Referring to FIG. 6, a display device DD may include a base layer BL, a circuit element layer DP-CL, a display element layer DP-ED, an input-sensing layer ISL, and an optical layer RCL sequentially stacked.

The display element layer DP-ED may include a photo-sensing element OPD of the photo sensor FX, a first light-emitting element ED1 of the first pixel PX1, and a pixel-defining layer PDL. In some cases, the recessed patterns GV defined in the pixel-defining layer PDL are disposed in non-light-emitting regions NA adjacent to the photo-sensing element OPD.

The first pixel PX1 may include the first light-emitting element ED1 and a first pixel driver PDP. The first light-emitting element ED1 may include an organic light-emitting element, a quantum dot light-emitting element, or a micro-light emitting diode (micro-LED) element. However, an embodiment is not necessarily limited thereto. The first light-emitting element ED1 may include various light-emitting elements as long as light is generated in response to an electrical signal or an amount of light is controllable. The first light-emitting element ED1 may be disposed in the first light-emitting region PXA-G1 and second light-emitting region PXA-G2 (see FIG. 5A). FIG. 6 exemplarily illustrates the first light-emitting element ED1 disposed in the first light-emitting region PXA-G1.

The photo sensor FX may include the photo-sensing element OPD and a sensor driver SDP. The photo-sensing element OPD may be disposed in the photo-sensing region SA (see FIG. 5A).

The photo-sensing element OPD may recognize light reflected from an external object. In an embodiment, the photo-sensing element OPD may be a biometric sensor which recognizes light reflected from a fingerprint and converts an optical signal into an electrical signal. For example, the photo-sensing element OPD may be configured to sense fingerprint information. In some cases, the photo-sensing element OPD may be configured to detect proximity, patterns, or ambient light, with the recessed patterns GV ensuring reliable sensing by suppressing leakage currents.

Emission light OT-L emitted from the first light-emitting element ED1 may be reflected from the fingerprint FG to be incident on the photo-sensing element OPD as reflected light IP-L. For example, the reflected light IP-L may be green light. The photo-sensing element OPD may receive the incident reflected light IP-L and convert the received light into an electrical signal.

The photo-sensing element OPD may include a first electrode AE, a hole control layer HCL, a photoelectric transformation layer OPL, an electron control layer ECL, and a second electrode CE sequentially stacked.

The first electrode AE may be disposed on the circuit element layer DP-CL. The first electrode AE may be exposed through a pixel opening PDL-OP in the pixel-defining layer PDL. The first electrode AE may be formed of a metal material, a metal alloy, or a conductive compound. In some embodiments, an intervening layer may be partially disposed between the first electrode AE and the pixel-defining layer PDL. In some embodiments, the first electrode AE may be directly disposed on the circuit element layer DP-CL.

The hole control layer HCL may be disposed on the first electrode AE and the pixel-defining layer PDL. The hole control layer HCL may be a single layer formed of a single material, a single layer formed of a plurality of different materials, or a multi-layered structure including a plurality of layers formed of a plurality of different materials. For example, the hole control layer HCL may be configured as a structure of a single layer such as a hole injection layer or a hole transport layer, or a single-layered structure formed of a hole injection material and a hole transport material. In an embodiment, the hole control layer HCL may include a hole transport layer, and may further include a hole injection layer.

The photoelectric transformation layer OPL may be disposed on the hole control layer HCL in the photo-sensing region SA. The photoelectric transformation layer OPL may include a light receiving material which receives light and converts the light into an electrical signal. In an embodiment, the photoelectric transformation layer OPL may include an organic light receiving material. However, materials from which the photoelectric transformation layer OPL is formed are not necessarily limited thereto. For example, the photoelectric transformation layer OPL may include an organic polymer material, such as a conjugated polymer.

The electron control layer ECL may be disposed on the photoelectric transformation layer OPL, a first light-emitting layer EML1, and the hole control layer HCL. For example, the electron control layer ECL may have an integral shape. The electron control layer ECL may be a single layer formed of a single material, a single layer formed of a plurality of different materials, or a multi-layered structure including a plurality of layers formed of a plurality of different materials. For example, the electron control layer ECL may be configured as a structure of a single layer such as an electron injection layer or an electron transport layer, or a single-layered structure formed of an electron injection material and an electron transport material. Additionally, the electron control layer ECL may include multiple stacked sub-layers sequentially disposed from the light-emitting layer. In an embodiment, the electron control layer ECL may include an electron transport layer, and an electron injection layer.

The second electrode CE may be disposed on the electron control layer ECL, and may be simultaneously formed through the same process. For example, the second electrode CE may have an integral shape. The second electrode CE may be a common electrode. However, the second electrode CE is not necessarily limited thereto. For example, the second electrode CE may be a transmissive electrode, a transflective electrode, or a reflective electrode.

The sensor driver SDP may be disposed on the circuit element layer DP-CL. The sensor driver SDP may include a sensor driving circuit electrically connected to the photo-sensing element OPD to drive the photo-sensing element OPD. In some cases, the sensor driver SDP may be disposed on a lower region of the circuit element layer DP-CL. For example, a lower surface of the sensor driver SDP may be coplanar with a lower surface of the circuit element layer DP-CL. In some cases, the first electrode AE may be in contact with an upper surface of the sensor driver SDP through the circuit element layer DP-CL.

The first light-emitting element ED1 may include a first electrode AE, a hole control layer HCL, a first light-emitting layer EML1, an electron control layer ECL, and a second electrode CE sequentially disposed. In one aspect, the first light-emitting element ED1 may be disposed in the first light-emitting region PXA-G1. The descriptions made for the first electrode AE, the hole control layer HCL, the electron control layer ECL, and the second electrode CE of the photo-sensing element OPD may be similarly applied to the first electrode AE, the hole control layer HCL, the electron control layer ECL, and the second electrode CE, and the difference is described.

The first light-emitting layer EML1 may be disposed on the hole control layer HCL. The first light-emitting layer EML1 may include an organic material and/or an inorganic material. The first light-emitting layer EML1 may generate light having a predetermined color. The first light-emitting layer EML1 may include an organic light-emitting material or a quantum dot material.

A pixel driver PDP1 may be disposed on the circuit element layer DP-CL. The pixel driver PDP1 may include a pixel driving circuit electrically connected to the first light-emitting element ED1 to drive the first light-emitting element ED1.

The pixel-defining layer PDL may be disposed on the circuit element layer DP-CL. In some cases, the pixel-defining layer PDL may overlap at least a portion of an upper surface and side surfaces of the first electrode AE. The pixel-defining layer PDL may include a black material. The pixel-defining layer PDL may include a black organic dye/pigment such as carbon black or aniline black. The pixel-defining layer PDL may be formed by mixing a blue organic material and a black organic material. The pixel-defining layer PDL may include a liquid-repellent organic material.

The pixel openings PDL-OP may be defined in the pixel-defining layer PDL. First, second, and third light-emitting elements and/or the photo-sensing elements OPD may be disposed in the pixel openings PDL-OP. The spatial arrangement of the pixel openings PDL-OP relative to recessed patterns GV provides localized electrical isolation between the disposed elements.

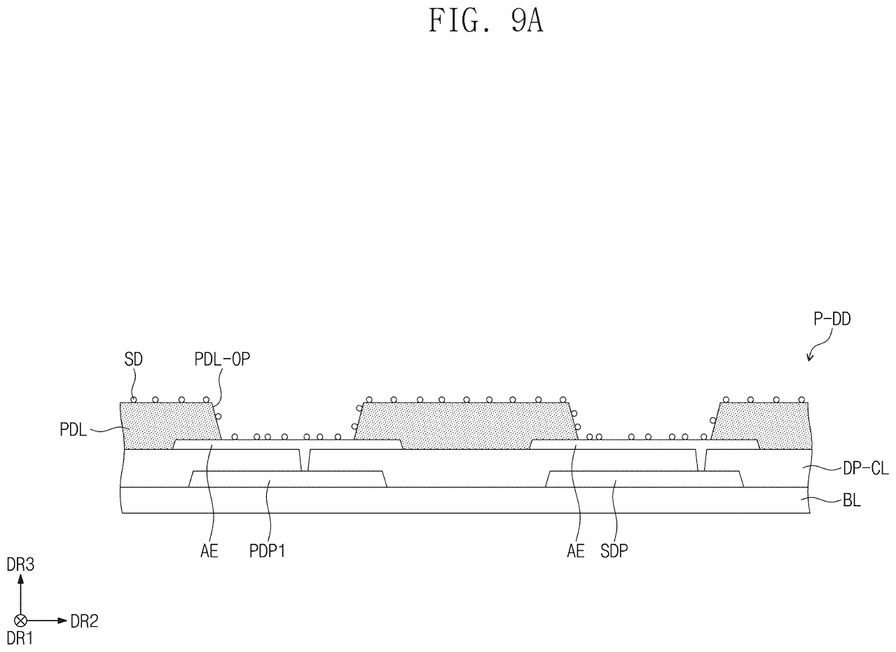

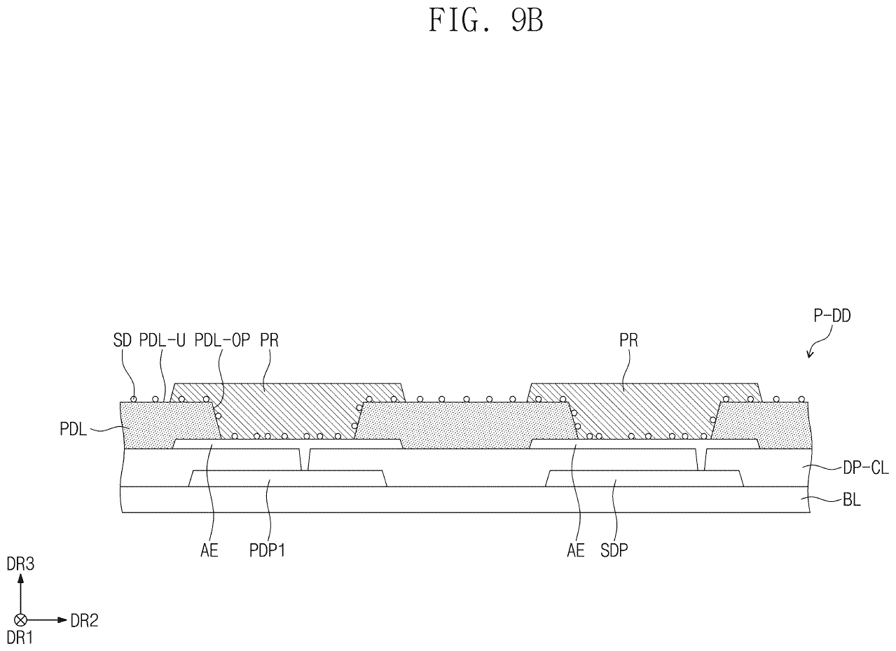

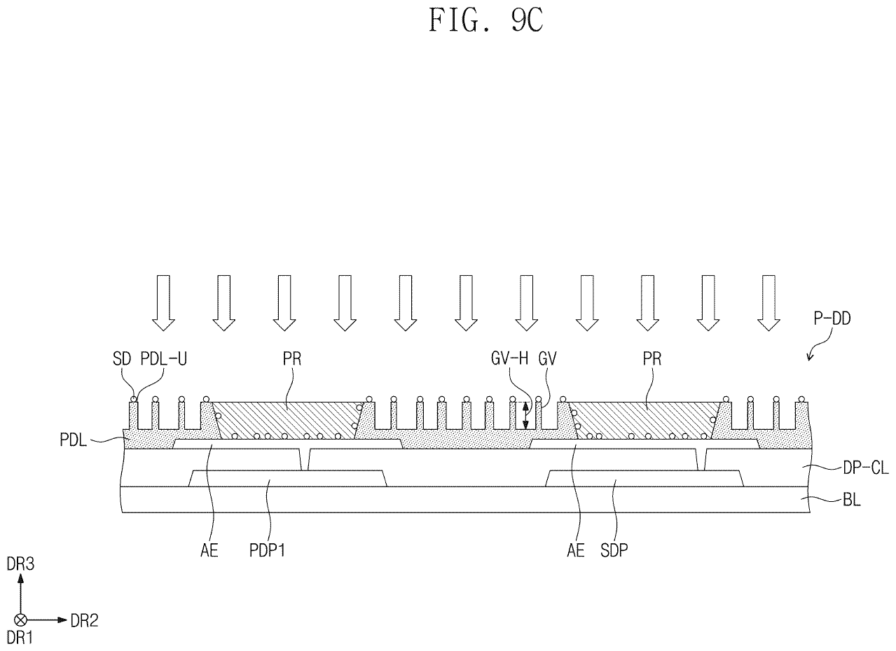

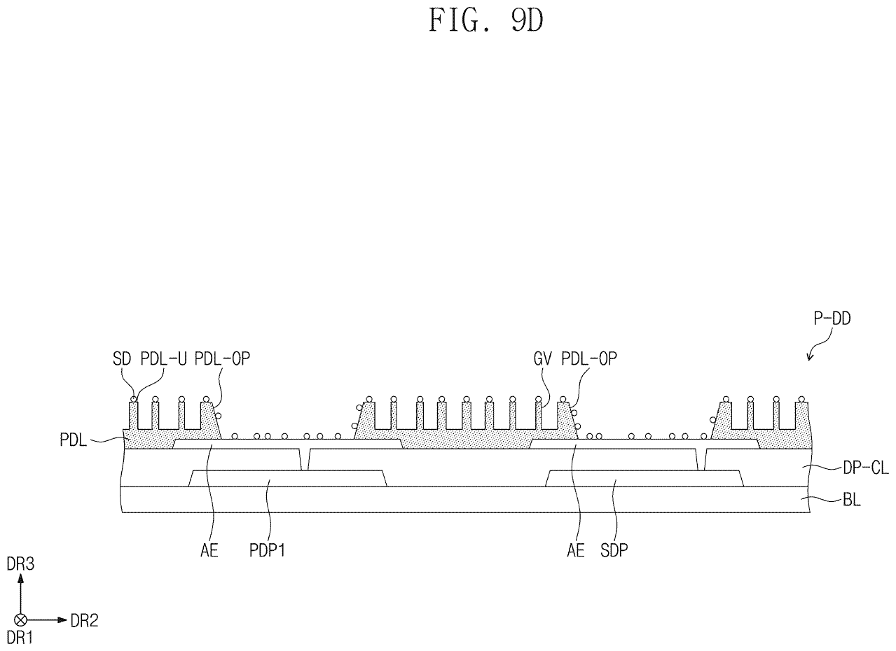

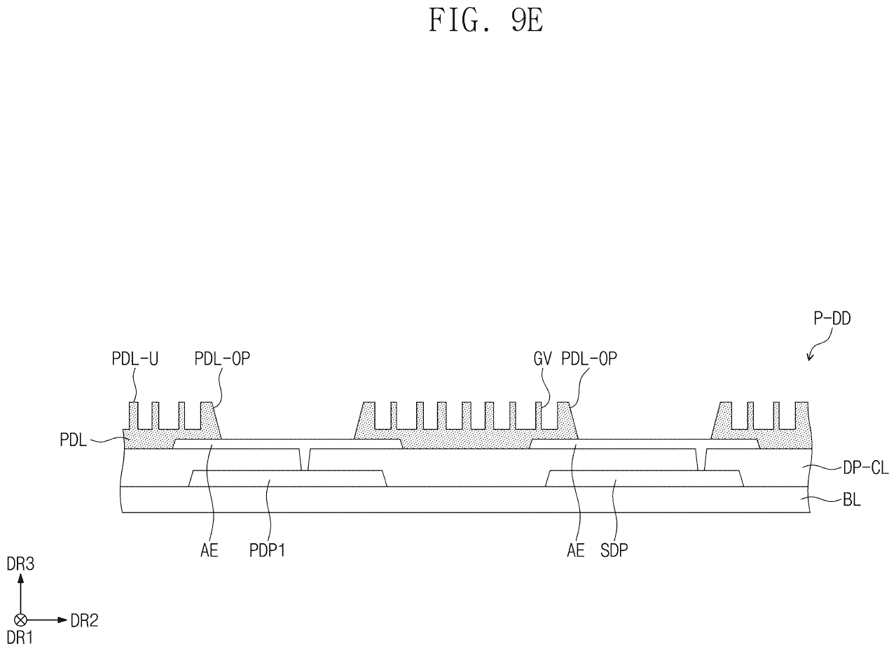

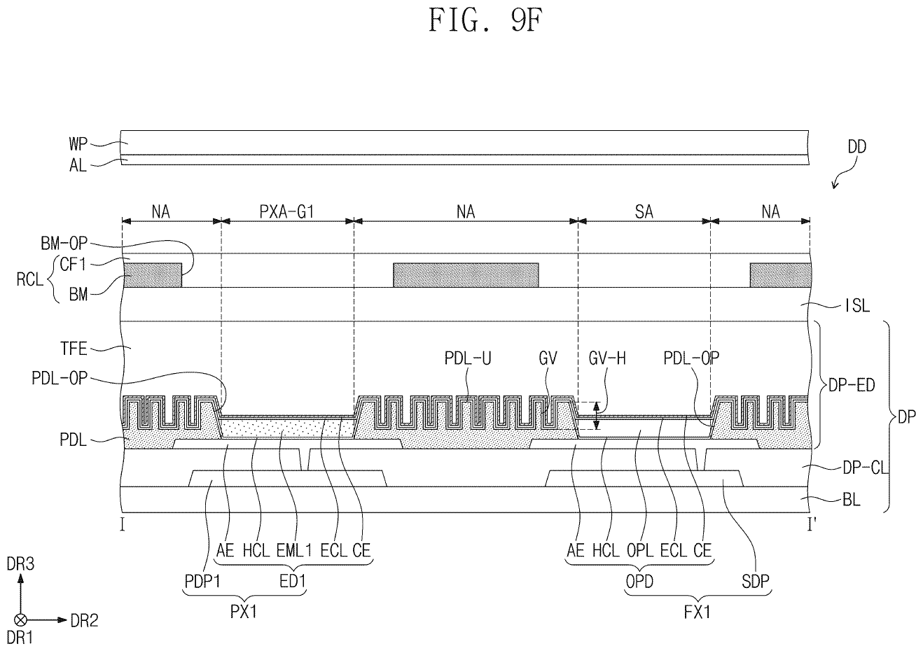

Recessed patterns GV may be formed in the pixel-defining layer PDL. An upper surface PDL-U of the pixel-defining layer PDL may be recessed along a direction opposed to the third direction DR3, thereby forming the recessed patterns GV. For example, during the manufacturing process, material of the pixel-defining layer PDL may be recessed towards the base layer Bl of the display device DD. The recessed patterns GV might not completely penetrate the pixel-defining layer PDL. The depths GV-H of the recessed patterns GV may be larger than the widths of blocking particles SD (see FIG. 9A). The recessed patterns GV may be configured to reduce a lateral leakage current. For example, the lateral leakage current may be reduced by increasing or disconnecting leakage paths between light-emitting elements and photo-sensing elements. Because the recessed patterns GV are randomly distributed based on the deposition of blocking particles, leakage suppression can be achieved without the need for additional alignment. Further detail on the recessed patterns GV is described with reference to FIGS. 7A and 7B.

In some embodiments, a capping layer may be disposed on the second electrode CE. The capping layer may serve to protect the second electrode CE from oxidation or mechanical damage and may further stabilize recessed regions formed in the pixel-defining layer PDL.

The optical layer RCL may include a light blocking layer BM and color filters. The color filters may include first, second, and third color filters CF1, CF2, and CF3. The first color filter may transmit green light, the second color filter may transmit red light, and the third color filter may transmit blue light. For example, FIG. 6 illustrates a first color filter CF1. In some cases, the second color filter CF2 and the third color filter CF3 may be substantially the same as the first color filter CF1. In some embodiments, the optical layer RCL may further include a white color filter or other light wave filters.

The light blocking layer BM may be disposed on the display element layer DP-ED. The light blocking layer BM may prevent a light leakage phenomenon and define boundaries between the adjacent color filters of different colors. The light blocking layer BM may be a black matrix. The light blocking layer BM may include an organic pigment or dye. The light blocking layer BM may include an organic light blocking material or an inorganic light blocking material which includes a black pigment or a black dye. Openings BM-OP which completely penetrate the light blocking layer BM in the third direction DR3 may be defined in the light blocking layer BM. In some cases, the placement of openings BM-OP is aligned with the recessed patterns GV of the pixel-defining layer PDL to maintain optical efficiency. In some cases, the width of each of the openings BM-OP is greater than each of a width of the first light-emitting element ED1 and a width of a photo-sensing element OPD.

FIGS. 7A and 7B are enlarged views of a part of FIG. 6.

FIGS. 7A and 7B illustrate two different structural configurations of a hole control layer HCL, an electron control layer ECL, and a second electrode CE when these layers extend across or are interrupted by a recessed pattern GV.

In the present disclosure, FIG. 7A illustrates a first case of a structural configuration of the hole control layer HCL, the electron control layer ECL, and the second electrode CE. FIG. 7B illustrates a second case of a structural configuration of the hole control layer HCL, the electron control layer ECL, and the second electrode CE. The first case of the configuration may be in a portion of a region overlapping the recessed pattern GV, and the second case of the configuration may be in another portion of the region overlapping the recessed pattern GV.

Referring to FIG. 7A, in an embodiment, the hole control layer HCL, the electron control layer ECL, and the second electrode CE may be formed on an inner side of the recessed pattern GV. Accordingly, a movement path of a leakage current from a first light-emitting element ED1 toward a photo-sensing element OPD may increase.

In the present disclosure, a current movement path from the first light-emitting element ED1 (see FIG. 6) toward the photo-sensing element OPD (see FIG. 6) via the hole control layer HCL or the electron control layer ECL may be referred to as a leakage path.

In some cases, a conventional display device includes a pixel-defining layer may have a flat upper surface, so that an electron movement path from a first light-emitting element to a photo-sensing element in a region overlapping the upper surface of the pixel-defining layer is parallel to the second direction DR2. According to embodiments of the present disclosure, a display device DD may have an additional path in the third direction DR3 as well as a path in the second direction DR2 due to the recessed pattern GV. For example, FIG. 7A illustrates a first path L1 and a second path L2 (each represented by an arrow) which are leakage paths extending in the third direction DR3 in addition to the lateral direction DR2. Accordingly, the display device DD may include a leakage path having a length relatively longer than a leakage path of a conventional display device. This increase in leakage path length raises the resistance to lateral leakage current and improves the isolation between the light-emitting element ED1 and the photo-sensing element OPD.

As the length of the leakage path increases, a resistance value of a lateral leakage current increases. Therefore, due to an increase in the resistance value of the lateral leakage current, the lateral leakage current may have a reduced influence on the photo-sensing element OPD. This suppression enhances the accuracy and stability of optical sensing functions integrated into the display device DD.

Referring to FIG. 7B, in an embodiment, at least some of the hole control layer HCL, the electron control layer ECL, and the second electrode CE may be disconnected on the inner side of the recessed pattern GV. For example, when a width GV-W of the recessed pattern GV is relatively large, some of the hole control layer HCL, the electron control layer ECL, and the second electrode CE, overlapping the recessed pattern GV, may be disconnected.

Since the hole control layer HCL, the electron control layer ECL, and the second electrode CE are sequentially stacked along the third direction DR3, the hole control layer HCL may have the largest separation distance, and the second electrode CE may have the lowest separation distance. For example, a separation distance is referred to as the distance between two adjacent elements (such as hole control layer HCL, the electron control layer ECL, and the second electrode CE) across the recessed pattern GV. In some cases, two adjacent second electrode CE may be connected to each other. FIG. 7B illustrates that the hole control layer HCL and the electron control layer ECL are disconnected, but the second electrode CE is connected. When the hole control layer HCL is disconnected, an end HCL-E of the hole control layer HCL may be exposed, and when the electron control layer ECL is disconnected, an end ECL-E of the electron control layer ECL may be exposed. However, an embodiment of the inventive concept is not necessarily limited thereto. For example, the hole control layer HCL may be disconnected, and the electron control layer ECL and the second electrode CE may be connected. In some cases, the disconnection effect reduces lateral leakage current by introducing discontinuities in conductive paths between the light-emitting element ED1 and the photo-sensing element OPD.

Due to the difference in the separation distance, the number of regions in which the hole control layer HCL or the electron control layer ECL is disconnected is relatively higher, and the number of regions in which the second electrode CE is disconnected is relatively lower in a display region DA. Accordingly, the resistance increases in the hole control layer HCL and the electron control layer ECL may be greater than the resistance increase in the second electrode CE. Therefore, a lateral leakage current may have a reduced influence on the photo-sensing element OPD.

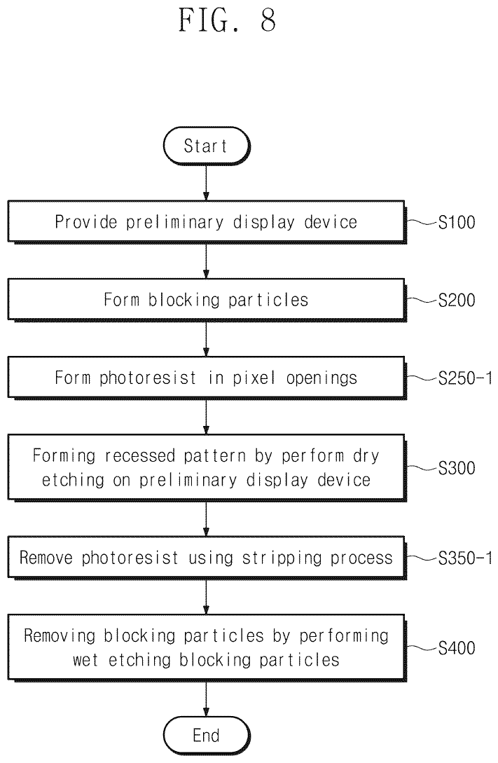

FIG. 8 is a flowchart illustrating a method for manufacturing a display device according to an embodiment of the inventive concept. For example, the method illustrates the formation of recessed patterns GV in a pixel-defining layer PDL through the deposition and removal of blocking particles.

According to embodiments of the present disclosure, the method for manufacturing the display device includes providing a preliminary display device P-DD (see FIG. 9A) which includes a base layer BL (see FIG. 9A), and the display element layer DP-ED (see FIG. 6) disposed on the base layer BL. The display element layer DP-ED may include a pixel-defining layer PDL (see FIG. 9A) including pixel openings PDL-OP (see FIG. 9A). The first electrodes AE (see FIG. 9A) are disposed in the pixel openings PDL-OP and a portion of first electrode may be covered by the pixel-defining layer PDL (S100). The method may further include forming blocking particles SD (see FIG. 9A) on the first electrode AE and the pixel-defining layer PDL (S200), perform dry etching on the preliminary display device P-DD (S300), and perform wet etching on the blocking particles SD (S400).

The method for manufacturing the display device may further include forming a photoresist PR (see FIG. 9B) in the pixel openings PDL-OP (see FIG. 9A9) after the formation of the blocking particles SD (S250-1).

The method for manufacturing the display device may further include a step of stripping the photoresist PR (see FIG. 9C) after performing the dry etching (S350-1).

FIGS. 9A to 9E are views illustrating each step in a method for manufacturing a display device according to an embodiment of the inventive concept.

FIG. 9A exemplarily illustrates operation S100 (S100) and operation S200 (S200) of the method. For example, the preliminary display device P-DD including the base layer BL, and the display element layer DP-ED disposed on the base layer BL is provided. The display element layer DP-ED may include the pixel-defining layer PDL having pixel openings PDL-OP, and the first electrodes AE may be disposed in the pixel openings PDL-OP. A portion of is the first electrodes AE may be covered by the pixel-defining layer PDL. At operation S200, the blocking particles SD may be formed on the first electrode AE and the pixel-defining layer PDL.

In the present disclosure, the preliminary display device P-DD may be referred to as a display device DD before being manufactured.

The blocking particles SD may be randomly or systematically arranged on the first electrode AE and the pixel-defining layer PDL. At least some of the blocking particles SD may be spaced apart from each other. The blocking particles SD may serve as a separator covering a predetermined region of the first electrode AE or the pixel-defining layer PDL. The blocking particles SD may be spaced apart from each other and be arranged in an island shape. For example, the blocking particles SD may be formed as discontinuous islands that act as localized hard masks during etching process.

The blocking particles SD may each include metal. For example, the blocking particles SD may each include one or more of silver (Ag), aluminum (Al), titanium (Ti), molybdenum (Mo), or nickel (Ni).

The blocking particles SD may have a maximum width of about 0.1 μm to about 10 μm. In the present disclosure, the maximum widths of the blocking particles SD may be measured from any direction.

The step for forming the blocking particles SD (S200) may be performed through one of a sputtering process, a chemical vapor deposition (CVD) process, or a nano imprint process.

Referring to FIG. 9B, the step for forming the photoresist PR in the pixel openings PDL-OP (S250-1) may be performed. The photoresist PR may be formed in the pixel openings PDL-OP through an inkjet method. The photoresist PR may be a positive photosensitive material or a negative photosensitive material. In some embodiments, the photoresist PR may be deposited by spin coating, spray coating, or other selective coating techniques.

The photoresist PR may cover the first electrode AE. The photoresist PR may cover a portion of the pixel-defining layer PDL. The photoresist PR may partially cover an upper surface PDL-U of the pixel-defining layer PDL. However, an embodiment of the inventive concept is not necessarily limited thereto. The photoresist PR might not cover the upper surface PDL-U of the pixel-defining layer PDL. The photoresist PR may cover some of the blocking particles SD. This partial coverage ensures that the blocking particles SD remain exposed to act as localized hard masks, while the first electrodes AE are shielded from subsequent etching process.

The photoresist PR may function to protect the first electrodes AE during a dry etching process, while ensuring the formation of recessed patterns GV in uncovered portions of the pixel-defining layer PDL.

Referring to FIG. 9C, recessed patterns may be formed by performing dry etching on the preliminary display device P-DD (S300) (see FIG. 8) using the blocking particles. For example, operation S300 (S300) may include forming recessed patterns GV by etching the upper surface PDL-U of the pixel-defining layer PDL in a thickness direction of the pixel-defining layer PDL. The recessed patterns GV are non-penetrating depressions that increase the leakage current path length without completely removing the pixel-defining layer PDL.

At operation S300 (S300), the pixel-defining layer PDL may be dry etched along a direction toward the base layer BL. However, regions shielded by the blocking particles SD in the pixel-defining layer PDL may be blocked from being etched. Accordingly, regions not covered by the blocking particles SD in the pixel-defining layer PDL may be selectively etched, thereby forming the recessed patterns GV.

Depths GV-H of the recessed patterns GV may be proportional to a time for which the preliminary display device P-DD is exposed during the dry etching process. For example, the depths GV-H of the recessed patterns GV may be adjusted based on a time for which the preliminary display device P-DD is exposed during the dry etching process. By controlling the etching duration, the recessed depth can be controlled and optimized to maximize leakage suppression without reducing the structural integrity of the pixel-defining layer PDL.

The depths GV-H of the recessed patterns GV may be formed with respect to the thicknesses of the hole control layer HCL (see FIG. 6), the electron control layer ECL (see FIG. 6), and the second electrode CE. For example, the depths GV-H of the recessed patterns GV may be determined to ensure that, among the hole control layer HCL (see FIG. 6), the electron control layer ECL (see FIG. 6), and the second electrode CE, the hole control layer HCL (see FIG. 6) or the electron control layer ECL (see FIG. 6) are disconnected.

Referring to FIG. 9D, the step for stripping the photoresist PR (S350-1) (see FIG. 8) may be performed. The photoresist PR may be selectively removed through a stripping process. For example, the photoresist PR may be removed using a stripper which decomposes a photosensitive solution through a chemical reaction. The stripper may include sulfuric acid or hydrogen peroxide. However, as long as the photoresist PR may be selectively removed, a type of strip process is not necessarily limited thereto. When the photoresist PR is removed, the blocking particles SD may be exposed.

Referring to FIG. 9E, the step for performing wet etching the blocking particles SD (S400) (see FIG. 8) is described. The blocking particles SD disposed on the first electrodes AE, and the blocking particles SD disposed on the upper surface of the pixel-defining layer PDL may be removed through a wet etching process. Suitable wet etchants are selected based on the metal composition of the blocking particles SD to ensure complete removal without damaging the first electrodes AE or the pixel-defining layer PDL.

Referring to FIG. 9F, an input-sensing layer ISL may be formed on a display panel DP using a continuous process without a separate adhesive layer or adhesive member. However, the input-sensing layer ISL is not necessarily limited thereto, and may be bonded to the display panel DP via an adhesive layer. The input-sensing layer ISL may be manufactured through a separate process from the display panel DP, and then may be fixed on an upper surface of the display panel DP via an adhesive layer. Because the recessed patterns GV in the pixel-defining layer PDL suppress lateral leakage current, the input-sensing layer ISL may enhance detection accuracy when integrated with the display panel DP.

Thereafter, an optical layer RCL may be formed by applying (or printing) a composition for the optical layer RCL on a base surface provided by the input-sensing layer ISL.

Then, a window WP may be disposed on a display module DM (or display device DD). An adhesive layer AL may be disposed between the window WP and the display module DM. The adhesive layer AL may include a transparent adhesive, such as an optically clear adhesive film (OCA), an optically clear resin (OCR), or a pressure sensitive adhesive film (PSA).

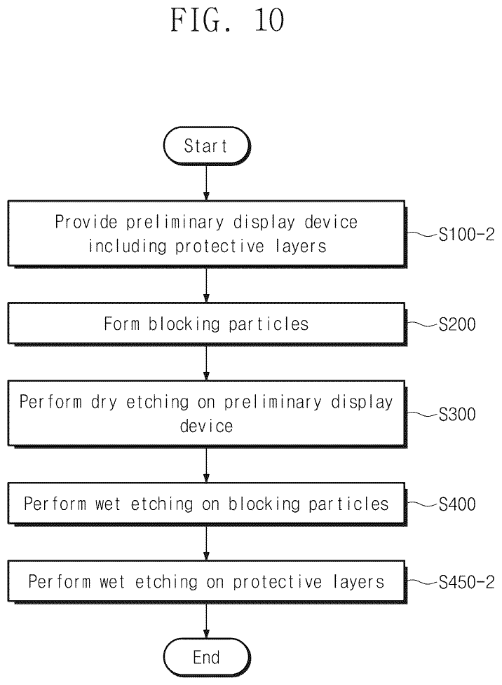

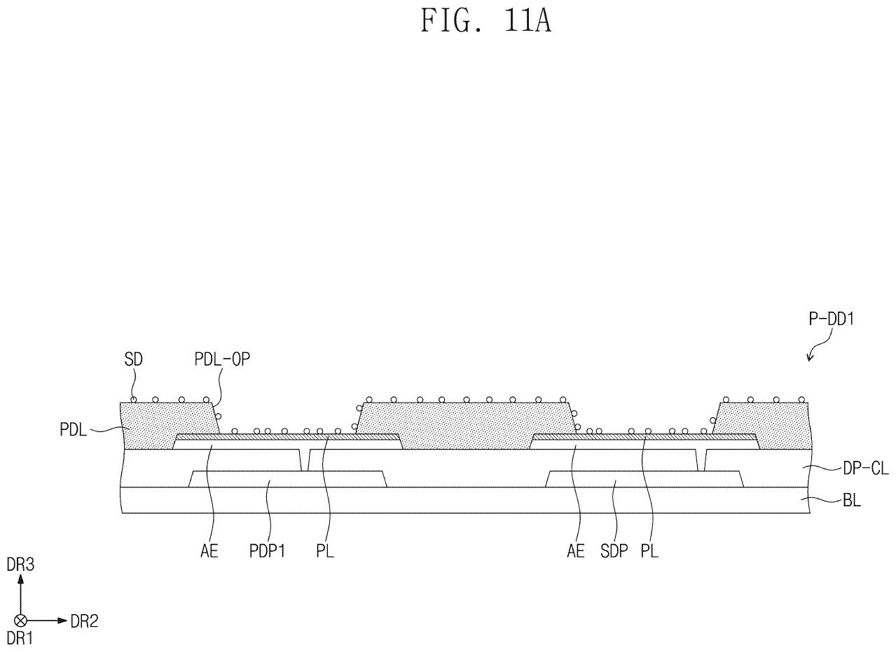

FIG. 10 is a flowchart illustrating a method for manufacturing a display device according to an embodiment of the inventive concept.

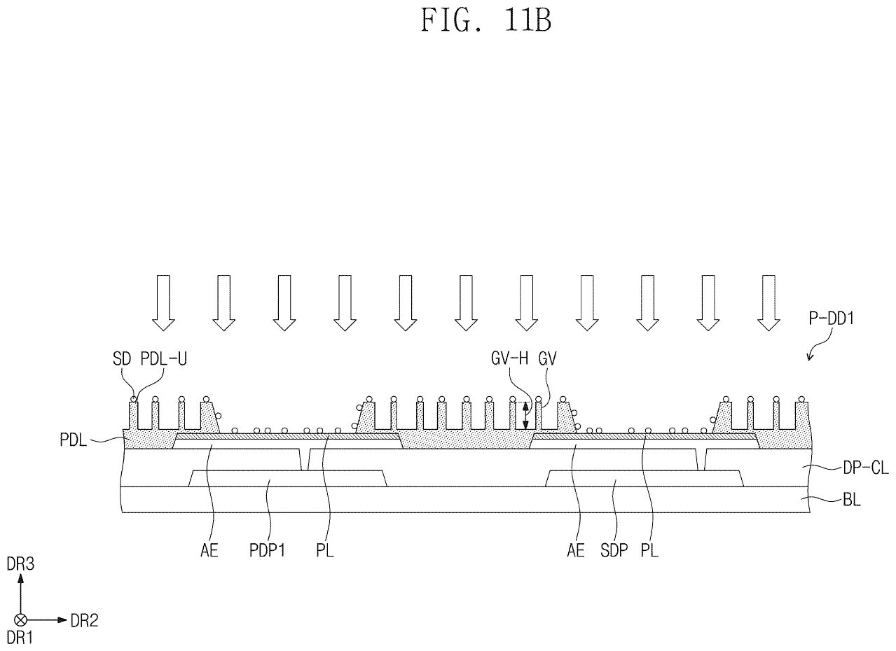

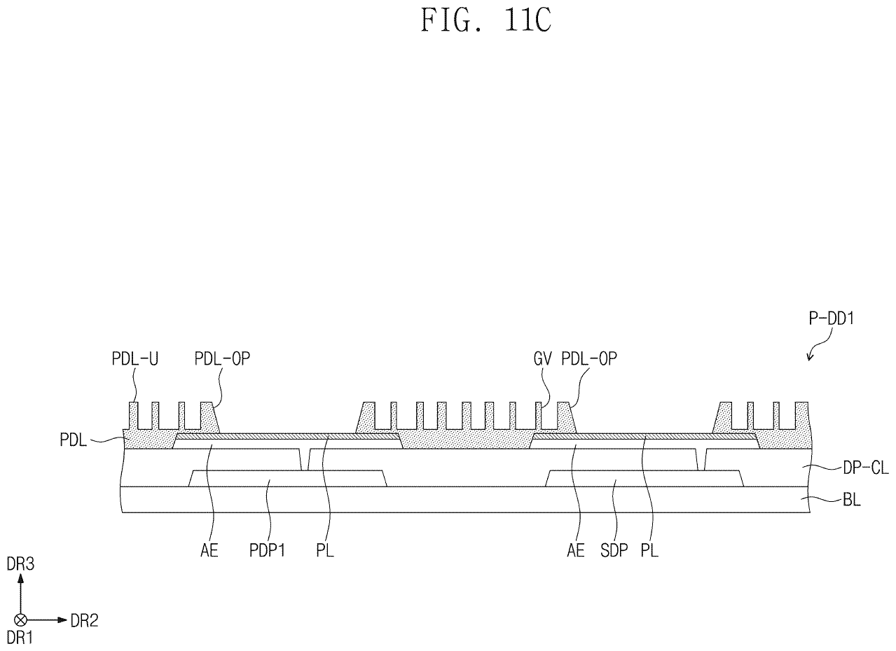

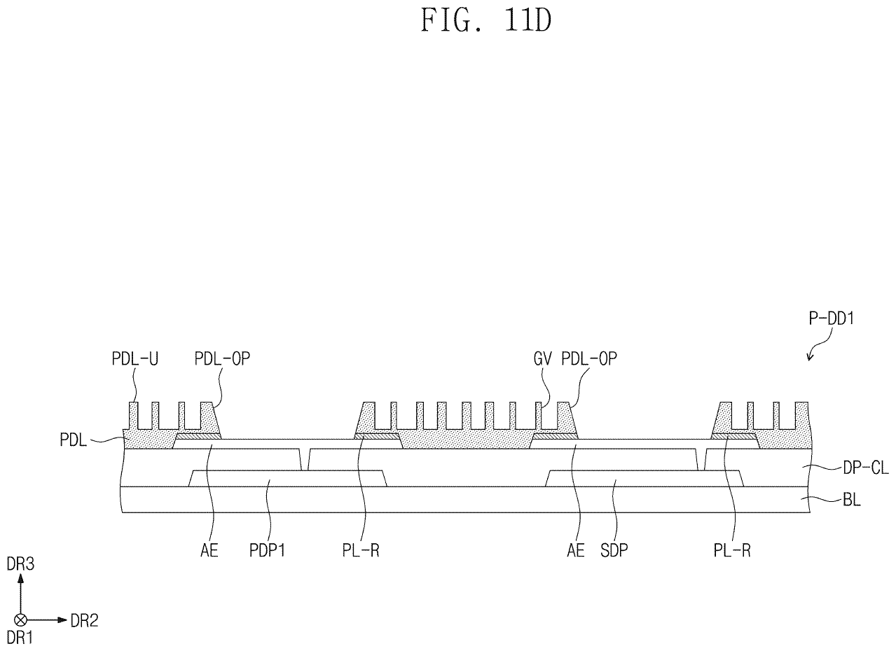

FIGS. 11A to 11D are views illustrating each step in a method for manufacturing a display device according to an embodiment of the inventive concept.

The same or similar reference numerals or symbols are used for the components same as or similar to those described in FIGS. 1 to 9F. Differences in the embodiments are described.

Referring to FIG. 10, the method for manufacturing the display device may include providing a preliminary display device P-DD1 (see FIG. 11A) which includes a base layer BL (see FIG. 11A), and a display element layer DP-ED disposed on the base layer BL. The display element layer DP-ED may include a pixel-defining layer PDL (see FIG. 11A) including pixel openings PDL-OP (see FIG. 11A). The first electrodes AE (see FIG. 11A) are disposed in the pixel openings PDL-OP and a portion of first electrode may be covered by the pixel-defining layer PDL. The display device P-DD1 may include a protective layers PL (see FIG. 11A) disposed on the first electrodes AE (S100-2). The method may further include forming blocking particles SD (see FIG. 11A) on the first electrode AE and the pixel-defining layer PDL (S200), perform dry etching on the preliminary display device P-DD1 (S300), perform wet etching on the protective layers PL exposed by the pixel opening PDL-OP (S350-2), and perform wet etching on the blocking particles SD (S400).

Referring to FIG. 11A, the step for providing the preliminary display device P-DD1 including the base layer BL, the display element layer DP-ED disposed on the base layer BL, and the protective layers PL disposed on the first electrodes AE (S100-2) (see FIG. 10) may be performed. Then, the step for forming the blocking particles SD on the first electrode AE and the pixel-defining layer PDL (S200) (see FIG. 10) may be performed.

The step for providing the preliminary display device P-DD1 (S100-2) (see FIG. 10) may include steps of forming the first electrode AE, forming the protective layer PL on the first electrode AE, and forming the pixel-defining layer PDL. For example, the preliminary display device P-DD1 may further include the protective layers PL disposed on the first electrodes AE, compared to the preliminary display device P-DD described with reference to FIG. 9A.

Some portions of the protective layers PL may be covered by the pixel-defining layer PDL. For example, at least an end portion of the protective layers PL may be covered by the pixel-defining layer PDL.

The protective layers PL may include materials which may be removed through a wet etching process. For example, the protective layers PL may include an inorganic oxide. For example, the protective layers PL may include ITO, IZO, ZnO, or similar compounds.

Referring to FIG. 11B, the step for performing dry etching on the preliminary display device P-DD1 (S300) (see FIG. 10) may be performed. The step of dry etching (S300) may include a step for forming recessed patterns GV by etching an upper surface PDL-U of the pixel-defining layer PDL in a thickness direction of the pixel-defining layer PDL. For example, the upper surface PDL-U of the pixel-defining layer PDL may be etched towards the base layer BL of the preliminary display device P-DD1.

In this step, the pixel-defining layer PDL may be dry etched along a direction opposed to the third direction DR3 (e.g., toward the base layer BL of the preliminary display device P-DD1). However, “regions shielded by the blocking particles SD in the pixel-defining layer PDL may be blocked from being etched. Accordingly, regions not covered by the blocking particles SD in the pixel-defining layer PDL may be selectively etched, thereby forming the recessed patterns GV.

Referring to FIGS. 11C and 11D, the step for wet etching on the blocking particles SD (S400) (see FIG. 10) and a step for wet etching on the protective layers PL exposed by the pixel opening PDL-OP (S450-2) (see FIG. 10) may be performed.

A portion of the protective layer PL may remain between the pixel-defining layer PDL and the first electrode AE. The remaining portion of the protective layer PL may be referred to as a remaining protective layer PL-R.

Thereafter, additional steps same as/similar to those described with reference to FIG. 9F may be performed. For example, the input-sensing layer ISL, the optical layer RCL, and the window WP may be sequentially formed on the preliminary display device P-DD1.

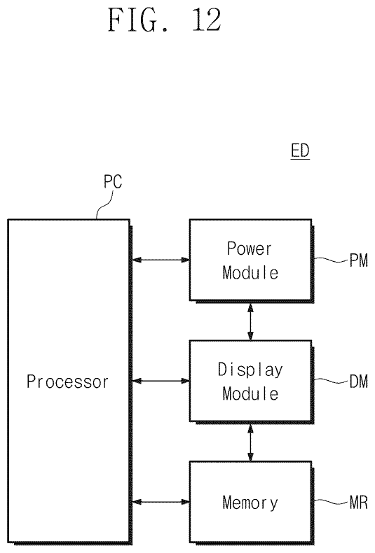

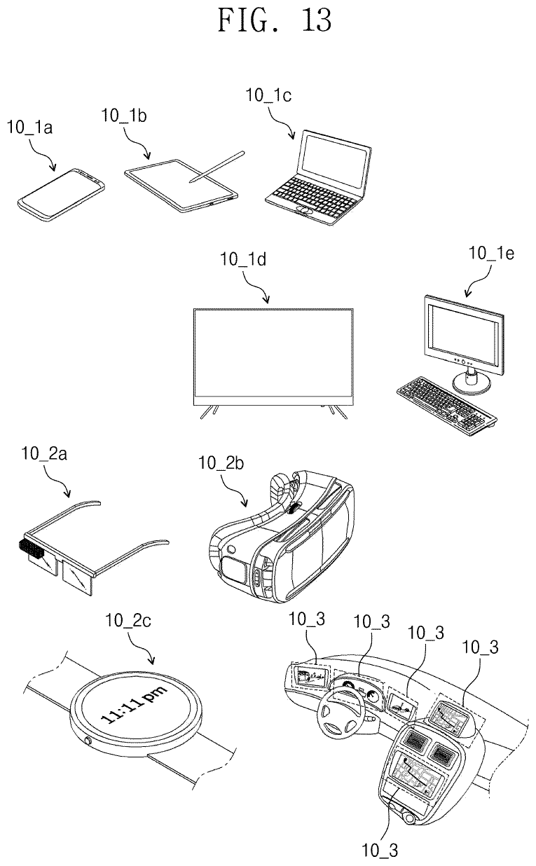

FIG. 12 is a block diagram of an electronic device according to an embodiment of the inventive concept. FIG. 13 is a schematic view of each of electronic devices according to various embodiments.

The electronic device according to the inventive concept may be provided in various forms. The electronic device according to the inventive concept may further include a module or a device which has additional functions.

Referring to FIG. 12, an electronic device ED according to an embodiment may include a display module DM, a processor PC, a memory MR, and a power module PM.

The processor PC may include at least one of a central processing unit (CPU), an application processor (AP), a graphic processing unit (GPU), a communication processor (CP), an image signal processor (ISP), or a controller.

The memory MR may store data information for operating the processor PC or the display module DM. When the processor PC executes an application stored in the memory MR, image data signals and/or input control signals are transmitted to the display module DM, and the display module DM may process the transmitted signals and generate image information through a display screen.

The power module PM may include a power supply module, such as a power adapter or a battery device, and a power conversion module configured to convert a power to for operating the electronic device ED.

Some of the modules may be included in one module may be included in the display module DM, and remaining modules may be provided separately from the display module DM in the electronic device ED.

FIG. 13 is a schematic view of each of electronic devices according to various embodiments.

Referring to FIG. 13, the electronic devices according to various embodiments may include an electronic device for displaying images, such as a smart phone ED-1a, a tablet computer ED-1b, a laptop computer ED-1c, a television (TV) ED-1d, a desktop monitor ED-1e. The electronic device may be implemented in a wearable electronic device including the display module, such as a smart glasses ED-2a, a head mounted display ED-2b, a smart watch ED-2c. The electronic device may be implemented in an automobile electronic device ED-3 including the display module, such as a center information display (CID) disposed on an instrument panel, a center fascia, or a dashboard of a car, and a room mirror display.

According to the inventive concept, a method for manufacturing a display device in which a lateral leakage current is reduced may be provided.

In the above, description has been made with reference to embodiments of the inventive concept, but those skilled or of ordinary skill in the art may understand that various modifications and changes may be made to the inventive concept insofar as such modifications and changes do not depart from the spirit and technical scope of the inventive concept.

What is claimed is:

1. A method for manufacturing a display device, the method comprising:
providing a preliminary display device including a base layer and a display element layer disposed on the base layer, wherein the display element layer includes a pixel-defining layer having pixel openings, and first electrodes disposed in the pixel openings, and wherein a portion of the first electrodes is covered by the pixel-defining layer;
forming blocking particles on the first electrodes and the pixel-defining layer;
forming a recessed pattern by performing dry etching on the preliminary display device using the blocking particles; and
removing the blocking particles by performing wet etching.

2. The method of claim 1, wherein:
the blocking particles are randomly arranged on the first electrodes and the pixel-defining layer.

3. The method of claim 1, further comprising:
forming a photoresist in the pixel openings,
wherein the photoresist covers at least some of the blocking particles.

4. The method of claim 3, further comprising:
removing the photoresist using a stripping process.

5. The method of claim 1, wherein the preliminary display device further comprises:
protective layers disposed on the first electrodes, wherein at least some portions of the protective layers are covered by the pixel-defining layer.

6. The method of claim 5, wherein:
the protective layers comprise an inorganic oxide.

7. The method of claim 5, further comprising:
performing wet etching on the protective layers in the pixel openings.

8. The method of claim 7, wherein:
a portion of the protective layer is disposed between the pixel-defining layer and the first electrode.

9. The method of claim 1, wherein:
the blocking particles each comprise metal.

10. The method of claim 9, wherein:
the metal comprises at least one of silver (Ag), aluminum (Al), titanium (Ti), molybdenum (Mo), or nickel (Ni).

11. The method of claim 1, wherein:
each of the blocking particles has an island shape.

12. The method of claim 1, wherein:
the blocking particles have a maximum width of about 0.1 μm to about 10 μm.

13. The method of claim 1, wherein:
at least some of the blocking particles are spaced apart from each other.

14. The method of claim 1, wherein:
the blocking particles are formed by performing at least one of a sputtering process, a chemical vapor deposition process, or a nano imprint process.

15. The method of claim 1, wherein:
the recessed pattern is formed by etching an upper surface of the pixel-defining layer towards the base layer.

16. The method of claim 15, wherein:
the recessed pattern does not overlap the blocking particles.

17. The method of claim 15, wherein:
a depth of the recessed pattern is greater than a width of each of the blocking particles, and the recessed pattern does not penetrate the pixel-defining layer.

18. The method of claim 1, wherein:
the base layer includes first, second, and third light-emitting regions and a photo-sensing region,
the photo-sensing region is surrounded by the first, second, and third light-emitting regions,
the first light-emitting region emits red light,
the second light-emitting region emits green light, and
the third light-emitting region emits blue light.

19. A method for manufacturing an electronic device including a display device, a processor, and a battery, the method comprising:
providing a preliminary display device including a base layer and a display element layer disposed on the base layer, wherein the display element layer includes a pixel-defining layer having pixel openings, and first electrodes disposed in the pixel openings, and wherein a portion of the first electrodes is covered by the pixel-defining layer;
forming blocking particles on the first electrodes and the pixel-defining layer;
forming a recessed pattern by performing dry etching on the preliminary display device using the blocking particles; and
removing the blocking particles by performing wet etching.

20. An electronic device configured to provide an image, comprising:
a display device;
a processor; and
a battery,
wherein the display device is manufactured using a method including:
providing a preliminary display device including a base layer and a display element layer disposed on the base layer, wherein the display element layer includes a pixel-defining layer having pixel openings, and first electrodes disposed in the pixel openings, and wherein a portion of the first electrodes is covered by the pixel-defining layer,
forming blocking particles on the first electrodes and the pixel-defining layer,
forming a recessed pattern by performing dry etching on the preliminary display device using the blocking particles, and
removing the blocking particles by performing wet etching.
